(19) United States
(12) Patent Application Publication
(10) Pub. No.: US 2012/0301673 A1
(43) Pub. Date: Nov. 29, 2012

(54) OXIDE FILM, PROCESS FOR PRODUCING SAME, TARGET, AND PROCESS FOR PRODUCING SINTERED OXIDE

(75) Inventors: Seiji Yamazoe, Yokohama-shi (JP); Takahiro Wada, Hirakata-shi (JP)

(73) Assignee: Ryukoku University, Kyoto (JP)

(21) Appl. No.: 13/576,567

(22) PCT Filed: Dec. 28, 2010
(86) PCT No.: PCT/JP2010/073700

§ 371 Date: Aug. 1, 2012

(51) Int. Cl. H01B 1/08; C04B 35/64; C23C 14/28; C23C 14/08; B05D 5/12; B32B 3/10; C23C 14/34

(52) U.S. Cl. 428/141; 252/519.1; 264/614; 204/192.1; 204/298.13; 427/126.3; 427/596

(57) ABSTRACT

One oxide film of the present invention is a film of an oxide (which can contain incidental impurities) containing one transition element selected from the group consisting of niobium (Nb) and tantalum (Ta) and copper (Cu). The oxide film is an aggregate of microcrystals, an amorphous form including microcrystals or an amorphous form, which shows no clear diffraction peak in an XRD analysis and has p-type conductivity as shown in the chart of FIG. 5 showing the results of XRD (X-ray diffraction) analyses of a first oxide film and a second oxide film. According to this oxide film, p-type conductivity higher than that of a conventional oxide film is obtained. This oxide film is an aggregate of microcrystals, an amorphous form containing microcrystals or an amorphous form, is consequently easily formed on a large substrate, and is therefore suitable also for industrial production.

### TECHNICAL FIELD

The present invention relates to an oxide film and a method for producing the same, and a target and a method for producing an oxide sintered body.

### BACKGROUND ART

Conventionally, various oxide films having transparency or conductivity have been researched. Particularly, a film having both transparency and conductivity is referred to as a transparent conductive film, and widely used as an important component material in devices such as flat panel displays and solar batteries.

Typical materials for transparent conductive films that have been so far employed are ITO (indium tin oxide) and ZnO (zinc oxide). ITO (indium tin oxide) is known particularly for high transparency and conductivity, is also stable as a material, and therefore has been used in various kinds of devices for many years. However, ITO shows only n-type conductivity, and therefore its range of application is limited. On the other hand, regarding ZnO (zinc oxide) that has recently received attention as a subject of research and development for performance improvement, not only pure zinc oxide but also zinc oxide, to which aluminum (Al) and chromium (Cr) are added, has been developed (see Patent Document 1). However, in the first place, zinc oxide has low stability to moisture or heat in comparison with ITO, and is therefore difficult to handle.

Incidentally, for transparent conductive films showing n-type conductivity, there exist a large number of types such as ZnO doped with Al and SnO₂ doped with fluorine as well as ITO described above. However, it can be said that research and development for performance improvement of transparent conductive films showing p-type conductivity are still halfway through. For example, it is disclosed that a film of CuAlO₂, a complex oxide of copper (Cu) and aluminum (Al), or a film of SrCu₂O₂, a complex oxide of copper (Cu) and strontium (Sr), shows p-type conductivity (see Non-Patent Document 1). However, the conductance thereof is very low. It is disclosed in Patent Documents 2 and 3 shown below that an oxide, to which several elements are added, has properties as a transparent conductive film, but both the documents lack specific disclosures concerning the conductivity and visible light transmittance for all the elements disclosed therein, and are therefore difficult to employ as technical data of transparent conductive films.

### PRIOR ART DOCUMENTS

### Patent Documents

Patent Document 1: Japanese Unexamined Patent Publication No. 2002-75061
Patent Document 2: Japanese Unexamined Patent Publication No. 2007-142028
Patent Document 3: Japanese Translation of PCT Application No. 2008-507842

### Non-Patent Document

Non-Patent Document 1: Jaroslaw Domaradzki and other three persons, “Transparent oxide semiconductors based on TiO₂ doped with V, Co and Pd elements”, Journal of Non-Crystalline Solids, 2006, vol. 352, pp. 2324-2327.

### SUMMARY OF THE INVENTION

### Problems to be Solved by the Invention

As described above, performance improvement of oxide films as conductive films, particularly transparent films, which show p-type conductivity, is far behind as compared with that of n-type conductive films. That is, p-type transparent conductive films that are currently developed mainly have the problem of low transparency or conductivity.

On the other hand, for crystalline oxide films, there may be the problem of orientation control of crystals which determines the properties of the films. In this sense, employment of a crystalline oxide film that does not adequately exhibit its performance unless it does not have a specific crystal orientation may pose a technical barrier for mass production or increasing in size of a substrate when industrialization is taken into consideration.

### Solutions to the Problems

The present invention solves at least one of the technical problems described above, and thereby significantly contributes to performance improvement of an oxide film as a p-type conductive film, particularly a p-type transparent conductive film. Considering that performance improvement of an oxide film having p-type conductivity would be absolutely necessary for expanding a range of application of conductive films, the present inventors have tried to employ not only elements that have been subject to study many years before but also new elements that have not been so far subject to study seriously for improving the conductivity or transparency of the oxide film. As a result of much trial and error, the present inventors have found that there exists a material that shows properties very different from those of an agglomerated form by forming the material into so called a thin film, and the properties of the film can contribute to solution of some of the problems described above. Further the present inventors have constantly conducted studies and as a result, also found that the material involves relatively mild production conditions for obtaining desired properties, so that the degree of freedom in production may be extremely increased. The present invention has been created through such findings and circumstances.

One oxide film of the present invention is a film of an oxide (which can contain incidental impurities) containing one transition element selected from the group consisting of niobium (Nb) and tantalum (Ta) and copper (Cu), wherein the oxide film is an aggregate of microcrystals, an amorphous form containing microcrystals or an amorphous form, and has p-type conductivity.

According to this oxide film, p-type conductivity higher than that of a conventional oxide film is obtained. This oxide normally shows crystallinity in an agglomerated form, but when the oxide is formed into a film form, it becomes an aggregate of microcrystals, an amorphous form containing microcrystals or an amorphous form and its conductivity as a p-type is dramatically improved. This oxide film is an aggregate of microcrystals, an amorphous form containing microcrystals or an amorphous form, is consequently easily formed on a large substrate, and is therefore also suitable for industrial production.

Another oxide film of the present invention is a film of an oxide (which can contain incidental impurities) including copper (Cu) and a transition element (niobium (Nb) or tantalum (Ta)), wherein the ratio of the number of atoms of the transition element to the copper (Cu) is such that the number of atoms of the transition element is 0.5 or more and less than 3 provided that the number of atoms of the copper (Cu) is 1, and the oxide film is an aggregate of microcrystals, an amorphous form containing microcrystals or an amorphous form, and has p-type conductivity.

According to this oxide film, p-type conductivity higher than that of a conventional oxide film is obtained. This oxide normally shows crystallinity in an agglomerated form, but when the oxide is formed into a film form, it becomes an aggregate of microcrystals, an amorphous form containing microcrystals or an amorphous form and its conductivity as a p-type is dramatically improved. By employing the specific elements described above and meeting the ratio of the number of atoms in the specific range described above, the transparency of the oxide film is significantly improved. In addition, this oxide film is an aggregate of microcrystals, an amorphous form containing microcrystals or an amorphous form, is consequently easily formed on a large substrate, and is therefore also suitable for industrial production.

One method of the present invention for producing an oxide film includes a step of scattering constituent atoms of a target of an oxide (which can contain incidental impurities) including one transition element selected from the group consisting of niobium (Nb) and tantalum (Ta) and copper (Cu) to form on a substrate a first oxide film (which can contain incidental impurities) which is an aggregate of microcrystals, an amorphous form containing microcrystals or an amorphous form and has p-type conductivity.

According to this method for producing an oxide film, an oxide film having p-type conductivity higher than that of a conventional oxide film is obtained. This oxide normally shows crystallinity in an agglomerated form, but when the oxide is formed into a film form, it becomes an aggregate of microcrystals, an amorphous form containing microcrystals or an amorphous form and its conductivity as a p-type is dramatically improved. In addition, according to this method for producing an oxide film, the oxide film is an aggregate of microcrystals, an amorphous form containing microcrystals or an amorphous form, and thus can be easily formed on a large substrate, and therefore an oxide film suitable for industrial production as well is obtained.

Another method of the present invention for producing an oxide film includes a step of scattering constituent atoms of a target of an oxide (which can contain incidental impurities) including copper (Cu) and a transition element (niobium (Nb) or tantalum (Ta)) to form on a substrate a first oxide film (which can contain incidental impurities) in which the ratio of the number of atoms of the transition element to the copper (Cu) is such that the number of atoms of the transition element is 0.5 or more and less than 3 provided that the number of atoms of the copper (Cu) is 1 and which is an aggregate of microcrystals, an amorphous form containing microcrystals or an amorphous form, and has p-type conductivity.

According to this method for producing an oxide film, an oxide film having p-type conductivity higher than that of a conventional oxide film is obtained. This oxide normally shows crystallinity in an agglomerated form, but when the oxide is formed into a film form, it becomes an aggregate of microcrystals, an amorphous form containing microcrystals or an amorphous form and its conductivity as a p-type is dramatically improved. Further, by employing the specific elements described above and meeting the ratio of the number of atoms in the specific range described above, the transparency of the oxide film is significantly improved. In addition, according to this method for producing an oxide film, the oxide film is an aggregate of microcrystals, an amorphous form containing microcrystals or an amorphous form, and thus can be easily formed on a large substrate, and therefore an oxide film suitable for industrial production as well is obtained.

One target of the present invention is an oxide (which can contain incidental impurities) including one transition element selected from the group consisting of niobium (Nb) and tantalum (Ta) and copper (Cu), wherein the ratio of the number of atoms of the transition element to the copper (Cu) is 0.25 or more and 4 or less provided that the number of atoms of the copper (Cu) is 1.

According to this target, an oxide film having p-type conductivity higher than that of a conventional oxide film can be formed by scattering a constituent material of the target by, for example, sputtering or irradiation of a pulse laser.

One method of the present invention for producing an oxide sintered body includes a mixing step of obtaining a mixture by mixing an oxide (which can contain incidental impurities) of one transition element selected from the group consisting of niobium (Nb) and tantalum (Ta) and an oxide (which can contain incidental impurities) of copper (Cu) in a ratio such that the ratio of the number of atoms of the transition element to the copper (Cu) is 0.25 or more and 4 or less provided that the number of atoms of the copper (Cu) is 1, a molding step of obtaining a molded product by compression-molding the mixture, and a sintering step of sintering the molded product by heating the molded product.

According to this method for producing an oxide sintered body, an oxide film having p-type conductivity higher than that of a conventional oxide film can be formed by utilizing the oxide sintered body formed by the production method as a target that is subject to, for example, sputtering or irradiation of a pulse laser. A sintered body generally allows easy handling in the market, and therefore a product excellent in distributability and industrial applicability is obtained.

In the present application, a “substrate” means typically a glass substrate, a semiconductor substrate, a metal substrate and a plastic substrate, but is not limited thereto. The “substrate” in the present application is not limited to a tabular structure, but can also include a curved structure. Further, in the present application, a “temperature of substrate” means a set temperature of a heater for heating a stand or an appliance for supporting, holding or storing the substrate unless otherwise specified. In the present application, an “oxide” and an “oxide film” can contain impurities that cannot be prevented from being mixed therein from a production viewpoint. Typical examples of these impurities include impurities that can be mixed during production of a target, impurities contained in various kinds of substrates, and impurities contained in water used in steps of producing various kinds of devices. Therefore, it cannot be said that the impurities can be necessarily detected by most advanced analytical instruments at the time of filing the present application, but for example, aluminum (Al), silicon (Si), iron (Fe), sodium (Na), calcium (Ca) and magnesium (Mg) are considered as typical impurities. In the present application, a “film of an oxide containing one transition element selected from the group consisting of niobium (Nb) and tantalum (Ta) and copper (Cu)” includes not only a film of a complex oxide of niobium (Nb) or tantalum (Ta) and copper (Cu) (for example Cu_{X}Nb_{Y}O_{Z} and Cu_{X}Ta_{Y}O_{Z}, where X, Y and Z represent an abundance ratio of each atom; the same applies hereinbelow), but also a film of a mixture of copper oxide (Cu_{X}O_{Y}) and niobium oxide (Nb_{X}O_{Y}) or tantalum oxide (Ta_{X}O_{Y}). Similarly, in the present application, a “film of an oxide including copper (Cu) and niobium (Nb)” includes not only a film of a complex oxide of niobium (Nb) and copper (Cu) (Cu_{X}Nb_{Y}O_{Z}), but also a film of a mixture of copper oxide (Cu_{X}O_{Y}) and niobium oxide (Nb_{X}O_{Y}).

### Advantages of the Invention

According to one oxide film of the present invention, p-type conductivity higher than that of a conventional oxide film is obtained. In addition, this oxide film is not required to have a specific crystal structure, this is easily formed on a large substrate, and is therefore also suitable for industrial production.

According to one method of the present invention for producing an oxide film, an oxide film having p-type conductivity higher than that of a conventional oxide film is obtained. This oxide normally shows crystallinity in an agglomerated form, but when the oxide is formed into a film form, it becomes an aggregate of microcrystals, an amorphous form containing microcrystals or an amorphous form and its conductivity as a p-type is dramatically improved. In addition, according to this method for producing an oxide film, the oxide film is an aggregate of microcrystals, an amorphous form containing microcrystals or an amorphous form, and thus can be easily formed on a large substrate, and therefore an oxide film suitable for industrial production as well is obtained.

According to one target of the present invention, an oxide film having p-type conductivity higher than that of a conventional oxide film can be formed by scattering a constituent material of the target by, for example, sputtering or irradiation of a pulse laser.

Further, according to one method of the present invention for producing an oxide sintered body, an oxide film having p-type conductivity higher than that of a conventional oxide film can be formed by utilizing the oxide sintered body formed by the production method as a target that is subject to, for example, sputtering or irradiation of a pulse laser. A sintered body generally allows easy handling in the market, and therefore a product excellent in distributability and industrial applicability is obtained.

### BRIEF DESCRIPTION OF THE DRAWINGS

FIG. 1 is an explanatory view of a production apparatus for a first oxide film in a first embodiment of the present invention.

FIG. 2A is an explanatory view showing one of processes of forming a second oxide film in the first embodiment of the present invention.

FIG. 2B is an explanatory view showing one of processes of forming the second oxide film in the first embodiment of the present invention.

FIG. 3 is a photograph showing the result of observing the surface of the first oxide film in the first embodiment of the present invention by an atomic force microscope (AFM).

FIG. 4 is a photograph showing the result of observing the surface of the second oxide film in the first embodiment of the present invention by an atomic force microscope (AFM).

FIG. 5 is a chart showing the results of XRD (X-ray diffraction) analyses of the first oxide film and the second oxide film in the first embodiment of the present invention.

FIG. 6 is a chart showing the results of analyses of the transmittances of the first oxide film and the second oxide film in the first embodiment of the present invention to a light ray having a wavelength principally in a visible light region.

FIG. 7A is a photograph showing a TEM (transmission electron microscope) image of the second oxide film in the first embodiment of the present invention.

FIG. 7B is a photograph with a part (X part) of FIG. 7A magnified.

FIG. 7C is a photograph with a part (Y part) of FIG. 7B magnified.

FIG. 8A is a photograph showing a TEM (transmission electron microscope) image of the first oxide film in the first embodiment of the present invention.

FIG. 8B is the result of electron diffraction analysis of a part (1-1) of FIG. 8A.

FIG. 8C is the result of electron diffraction analysis of a part (1-2) of FIG. 8A.

FIG. 8D is the result of electron diffraction analysis of a part (2) of FIG. 8A.

FIG. 8E is the result of electron diffraction analysis of a part (3-1) of FIG. 8A.

FIG. 8F is the result of electron diffraction analysis of a part (3-2) of FIG. 8A.

FIG. 9A is a photograph showing a TEM (transmission electron microscope) image of another second oxide film in the first embodiment of the present invention.

FIG. 9B is the result of electron diffraction analysis of a part (1) of FIG. 9A.

FIG. 9C is the result of electron diffraction analysis of a part (2) of FIG. 9A.

FIG. 9D is the result of electron diffraction analysis of a part (3) of FIG. 9A.

FIG. 9E is the result of electron diffraction analysis of a part (4) of FIG. 9A.

FIG. 9F is the result of electron diffraction analysis of a part (5) of FIG. 9A.

FIG. 9G is the result of electron diffraction analysis of a part (6) of FIG. 9A.

FIG. 10A is a photograph showing a TEM (transmission electron microscope) image of another second oxide film in the first embodiment of the present invention.

FIG. 10B is the result of electron diffraction analysis of a part (1-1) of FIG. 10A.

FIG. 10C is the result of electron diffraction analysis of a part (1-2) of FIG. 10A.

FIG. 10D is the result of electron diffraction analysis of a part (2) of FIG. 10A.

FIG. 10E is the result of electron diffraction analysis of a part (3-1) of FIG. 10A.

FIG. 10F is the result of electron diffraction analysis of a part (3-2) of FIG. 10A.

FIG. 11A is a graph showing a change in resistivity to a change in temperature in the second oxide film in the first embodiment of the present invention.

FIG. 11B is a graph showing a change in carrier concentration to a change in temperature in the second oxide film in the first embodiment of the present invention.

FIG. 12 is a chart showing the results of analyses of the transmittances of the first oxide film and the second oxide film in a variation (1) of the first embodiment of the present invention to a light ray having a wavelength principally in a visible light region.

FIG. 13 is a chart showing the results of XRD (X-ray diffraction) analyses of the first oxide film and the second oxide film in a second embodiment of the present invention.

FIG. 14 is a chart showing the result of analysis of the transmittance of the second oxide film in a variation (1) of the second embodiment of the present invention to a light ray having a wavelength principally in a visible light region.

FIG. 15 is a chart showing the results of XRD (X-ray diffraction) analyses of the first oxide film and the second oxide film in a third embodiment of the present invention.

FIG. 16 is a chart showing the results of XRD (X-ray diffraction) analyses of the first oxide film and the second oxide film in the third embodiment of the present invention.

FIG. 17 is a chart showing the result of analysis of the transmittance of the first oxide film of another embodiment of the present invention to a light ray having a wavelength principally in a visible light region.

FIG. 18 is a chart showing the result of XRD (X-ray diffraction) analysis of the first oxide film of another embodiment of the present invention.

### DESCRIPTION OF REFERENCE SIGNS

10: Substrate
11: First oxide film
12: Second oxide film
20: Pulse laser deposition apparatus
21: Chamber
22: Excimer laser
23: Lens
24: Holder
25a: Oxygen gas cylinder
25b: Nitrogen gas cylinder
26: Inlet
27: Stage
28: Evacuation port
29: Vacuum pump
30: Target

### EMBODIMENTS OF THE INVENTION

Embodiments of the present invention will be described in detail based on accompanying drawings. It is to be noted that in the description, common parts are given common reference signs unless otherwise specified throughout the drawings. In the drawings, each of components of the embodiments is not necessarily shown with a mutual scale ratio maintained. Some signs can be omitted for the sake of clarity of each drawing.

### First Embodiment

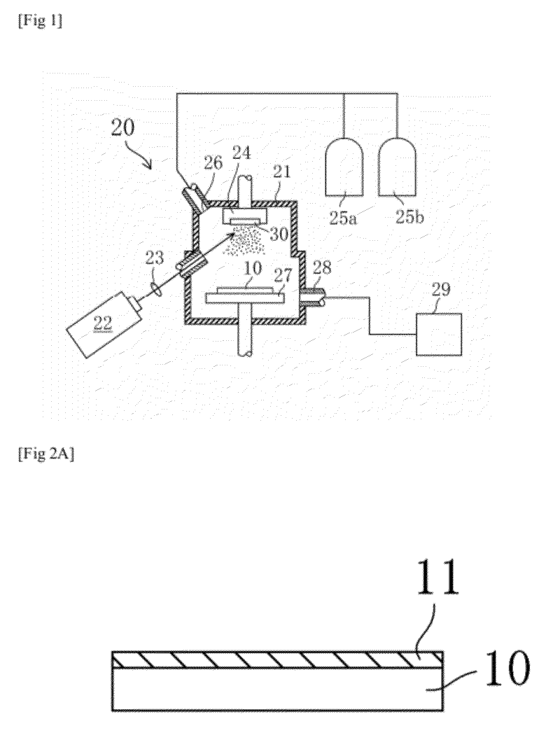

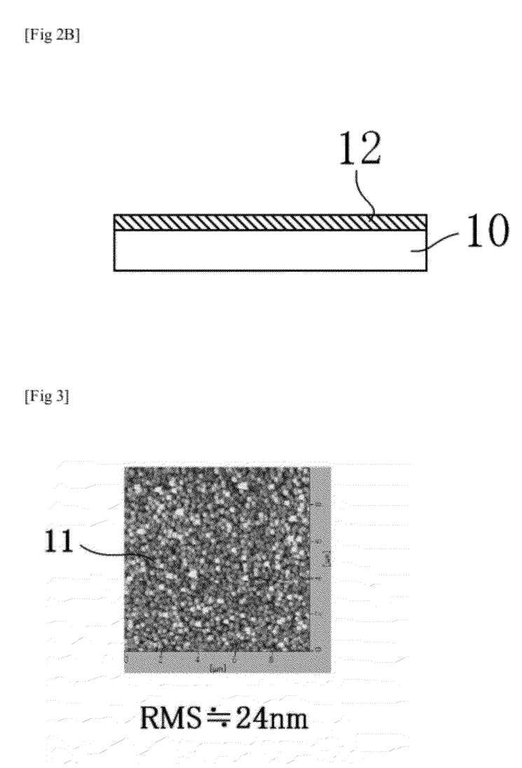

In this embodiment, an oxide film including copper (Cu) and niobium (Nb) and a method for producing the same will be described. FIG. 1 is an explanatory view of a production apparatus for a first oxide film in this embodiment. FIGS. 2A and 2B are explanatory views showing one of processes of forming a second oxide film in this embodiment.

In this embodiment, prior to production of an oxide film as a final object, an oxide sintered body as a raw material for forming the oxide film was produced. First, copper oxide (Cu₂O), i.e. an oxide of monovalent copper (Cu) and Nb₂O₅, i.e. an oxide of pentavalent niobium (Nb) were physically mixed. In this embodiment, the oxides were mixed using a known grinding mixer (manufactured by Ishikawa Kojo; Model AGA; the same applies hereinbelow). The two oxides were mixed so that the stoichiometric ratio of Nb and Cu was almost 1:1. For copper oxide (Cu₂O) of this embodiment, copper oxide manufactured by Kojundo Chemical Lab. Co., Ltd. and having a nominal purity of 99.9% was employed. For Nb₂O₅ of this embodiment, Nb₂O₅ manufactured by Kojundo Chemical Lab. Co., Ltd. and having a nominal purity of 99.9% was employed.

Next, in this embodiment, a molded product of the oxides was obtained by compression-molding a powder of a mixture of the oxides using a commercially available tablet molding machine (manufactured by NPa SYSTEM CO., LTD.; Model TB-5H). Pressure applied at this time was 35 MPa. A baking step was carried out for 4 hours using a commercially available muffle furnace (manufactured by Motoyama; Model MS-2520) heated to 950° C. with the molded product placed on the powdered mixture placed on an alumina plate.

An oxide sintered body obtained through the baking step had a relative density of about 90%. For the crystal structure of this oxide sintered body, measurements and analyses were carried out using an X-ray diffraction (XRD) analyzer (manufactured by Rigaku Corporation; product name “Automatic X-Ray Diffractometer RINT (registered trademark) 2400”). As a result, the oxide sintered body was found to have a crystal structure of CuNbO₃. Incidentally, a θ/2θ method was employed in the XRD measurement. A voltage in X-ray irradiation was 40 kV and a tube current was 100 mA. A target of an X-ray generating section was copper. All of the following XRD analyses were carried out using the aforementioned XRD analyzer.

Thereafter, an oxide film is produced on a substrate 10 using a pulse laser deposition apparatus 20 as shown in FIG. 1. A laser source of the pulse laser deposition apparatus 20 was Model Compex 201 manufactured by Lambda Physik AG, and its chamber was a pulse laser deposition apparatus manufactured by Neocera Inc. In this embodiment, the substrate 10 is a borosilicate glass substrate. The oxide sintered body described above was employed as a target 30. The substrate 10 was attached for placing via liquid indium onto a stage (or substrate holder; hereinafter uniformly referred to as stage) 27 within a chamber 21 exposed to the atmosphere, and air within the chamber 21 was then evacuated from an evacuation port 28 using a known vacuum pump 29. Air was evacuated until pressure within the chamber 21 reached the order of 10⁻⁴ Pa, and the temperature of a heater (not shown) within the stage 27 was then set to 500° C.

After a while, oxygen (O₂) and nitrogen (N₂) were fed into the chamber 21 through an inlet 26 from an oxygen gas cylinder 25a and a nitrogen gas cylinder 25b. In a step of deposition of an oxide film in this embodiment, evacuation by the vacuum pump 29 was adjusted so that the equilibrium pressure of oxygen within the chamber 21 was 0.027 Pa. In this embodiment, only oxygen gas was introduced, but the present invention is not limited thereto. For example, in place of nitrogen (N₂) gas, an inert gas such as helium gas (He) or argon (Ar) gas may be introduced along with oxygen gas. Alternatively, oxygen gas alone may be introduced. The equilibrium pressure of oxygen within chamber 21 in this embodiment was 0.027 Pa, but even if the equilibrium pressure is set to different pressure (for example 0.005 Pa or more and 100 Pa or less), an oxide film similar to the oxide film of this embodiment can be formed.

Thereafter, a pulse krypton fluoride (KrF) excimer laser (wavelength 248 nm) 22 is collected by a lens 23, and then emitted toward the target 30 held in a holder 24. By scattering the constituent atoms of the target 30 including the oxide sintered body by the excimer laser irradiation, a first oxide film 11 is formed on the substrate 10 as shown in FIG. 2A. Here, the composition ratio of the first oxide film 11 of this embodiment is almost equal to that of the oxide sintered body that is the target 30. Therefore, the composition ratio is such that a ratio of Nb to Cu is almost 1. The oscillatory frequency of the excimer laser of this embodiment was 10 Hz, energy per unit area of unit pulse was 200 mJ per pulse, and the number of irradiations was 100,000.

Further, after formation of the oxide film 11, the substrate 10 was taken out from the chamber 21 exposed to the atmosphere. Indium attached on the back surface of the substrate 10 was removed by hydrochloric acid, and the first oxide film 11 on the substrate 10 was then heat-treated (annealed) under a condition of 300° C. for 2 hours within a chamber having an atmosphere that had an oxygen concentration of less than 1% by feeding nitrogen (N₂) gas. As a result, a second oxide film 12 was formed on the substrate 10 as shown in FIG. 2B.

Here, the present inventors observed the surfaces of the first oxide film 11 and the second oxide film 12 obtained in this embodiment using an atomic force microscope (AFM) (manufactured by SII NanoTechnology Inc.; Model SPI-3700/SPA-300″). As a result, patterns considered as corrugation and granular matters were not particularly observed for the first oxide film 11. On the other hand, several patterns considered as granular matters were visually recognized for the second oxide film 12. The thickness of the second oxide film 12 was measured using a laser microscope (manufactured by KEYENCE CORPORATION; product name “Color 3D Laser Microscope VK-850”), and resultantly found to be about 150 nm. All of the following surface observations were made using the aforementioned atomic force microscope. All of the following thickness measurements were made using the aforementioned laser microscope and a scanning electron microscope (VE-9800) manufactured by KEYENCE CORPORATION.

The present inventors analyzed the crystal conditions of the first oxide film 11 and the second oxide film 12 by XRD (X-ray diffraction). As a result, for both the first oxide film 11 and the second oxide film 12, no peak was clearly observed at 2θ of 20° to 30° except for a broad halo peak considered to result from amorphousness as shown in FIG. 5. Therefore, when considering the results of the XRD analysis, both the first oxide film 11 and the second oxide film 12 are considered to be aggregates of microcrystals, amorphous forms including microcrystals or amorphous forms, which show no clear diffraction peak in the XRD analysis. Here, the present inventors also carried out an XRD analysis of the second oxide film where the first oxide film 11 was heat-treated under conditions of 200° C., 400° C. and 500° C. for 2 hours in addition to this embodiment. As a result, the film is considered to be an aggregate of microcrystals, an amorphous form including microcrystals or an amorphous form, which shows no clear diffraction peak in the XRD analysis, like the results in this embodiment, for all the temperatures of 200° C., 400° C. and 500° C.

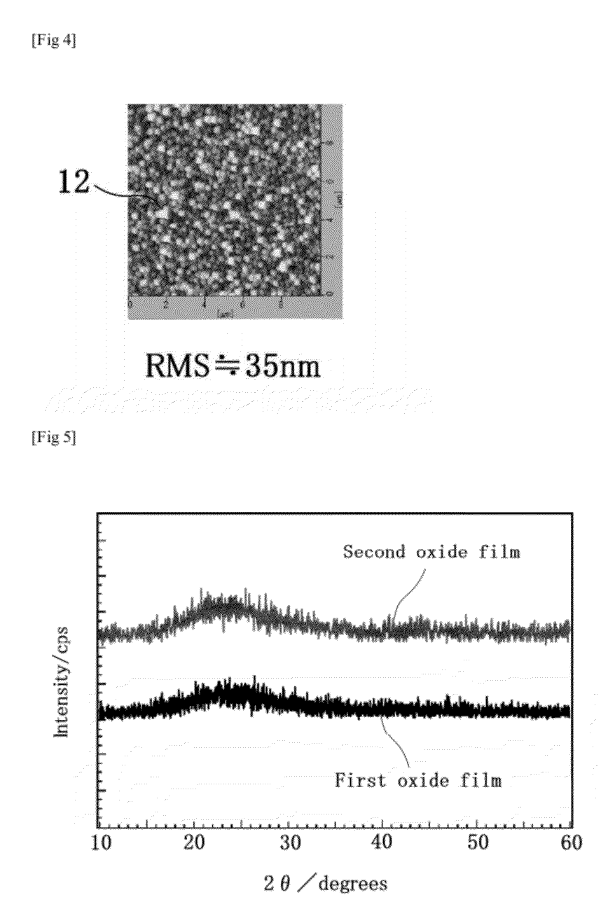

The present inventors analyzed the surface roughnesses of the first oxide film 11 and the second oxide film 12 by an atomic force microscope. As a result, it was found that the root mean square roughness (RMS) of the surface (hereinafter also referred to simply as “surface roughness”) of the first oxide film 11 in this embodiment was about 24 nm as shown in FIG. 3, and the surface roughness of the second oxide film 12 was about 35 nm as shown in FIG. 4. Here, the present inventors also analyzed the surface roughness of the second oxide film where the first oxide film 11 was heat-treated under conditions of 200° C. and 500° C. for 2 hours in addition to this embodiment. As a result, a film having very high flatness was formed like the results in this embodiment for the condition of 200° C., but the surface roughness of the film considerably increased (for example, RMS exceeded about 50 nm) in comparison with the surface roughness in this embodiment for the condition of 500° C.

The present inventors analyzed the electrical properties and conductances of the first oxide film 11 and the second oxide film 12 using a Hall effect measurement apparatus (manufactured by ECOPIA, INC.; product name “Hall Effect Measurement System HMS-3000 Ver. 3.5”). As a result, the first oxide film 11 of this embodiment had p-type conductivity and had a conductance of about 0.011 S/cm. On the other hand, the second oxide film 12 of this embodiment had p-type conductivity and had a conductance of about 21.2 S/cm. Therefore, it was found that the conductance of the second oxide film 12 could be increased by a factor of about 2000 relative to that of the first oxide film 11 by the heat treatment. The conductance of the second oxide film 12 is an extremely high value that is unprecedented as a p-type conductance as far as the present inventors know. The band gap of the second oxide film 12 was found to be about 2.6 eV. Therefore, it became clear that the second oxide film 12 of this embodiment had a relatively broad bandgap. Further, the present inventors also analyzed the electrical properties and conductance of the second oxide film where the first oxide film 11 was heat-treated under a condition of 200° C. for 2 hours in addition to this embodiment. As a result, the second oxide film had p-type conductivity and had a conductance of about 0.68 S/cm. It can be said that even the value is a conductance much higher than that previously achieved.

Therefore, by the analyses of the electrical properties and conductance, it became clear that heat treatment of the first oxide film 11 at a temperature in a range of 200° C. or higher and lower than 400° C. would contribute to dramatic improvement of conductivity as a p-type. Particularly, it is preferable to heat-treat the first oxide film 11 at a temperature in a range of 200° C. or higher and 300° C. or lower from the aforementioned viewpoint. At any rate, this finding applies to even a film of an oxide (which can contain incidental impurities) containing niobium (Nb) and copper (Cu), wherein the ratio of the number of atoms of niobium (Nb) to copper (Cu) is such that the number of atoms of niobium (Nb) is 0.5 or more and 4 or less provided that the number of atoms of copper is 1, at least in the sense that the oxide film has p-type conductivity. All the following measurements of the electrical properties and conductance were made using the Hall effect measurement apparatus described above.

The present inventors analyzed the visible light transmittances (hereinafter referred to simply as “visible light transmittance” or “transmittance”) of the first oxide film 11 and the second oxide film 12 using a multi-channel spectrometer (manufactured by Hamamatsu Photonics K.K.; product name “Multi-Channel Spectrometer PMA-12”). CCD Linear Image Sensor “C1027-02” having a detection sensitivity in a wavelength range of 300 nm to 1100 nm was used as a photo-detecting device.

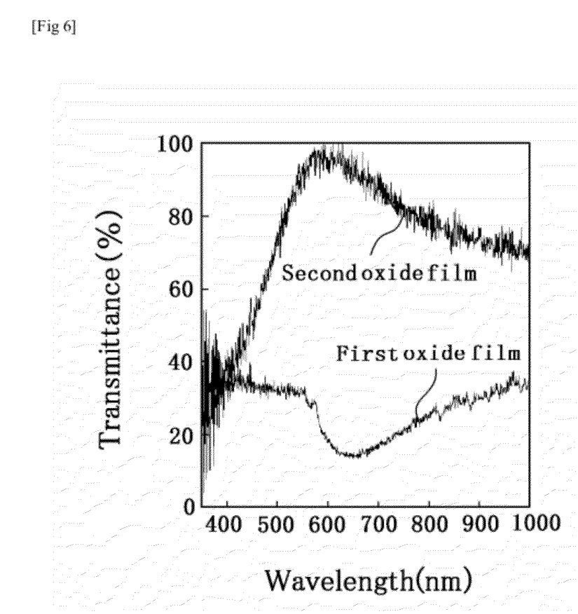

FIG. 6 is a chart showing the results of analyses of the transmittances of the first oxide film 11 and the second oxide film 12 in this embodiment to a light ray having a wavelength principally in a visible light region. It was found that as shown in FIG. 6, the transmittance of the first oxide film 11 to a light ray having a wavelength of 400 nm or more and 800 nm or less was 40% or less, while for the second oxide film 12, the transmittance in the same range was dramatically improved, and particularly the transmittance to a light ray having a wavelength of about 470 nm or more and 1000 nm or less was 60% or more. Particularly, in a range of 500 nm or more and 800 nm or less, the transmittance was 70% or more.

Here, the present inventors also analyzed the visible light transmittance of the second oxide film where the first oxide film 11 was heat-treated under conditions of 200° C., 400° C. and 500° C. for 2 hours in addition to this embodiment. As a result, it became clear that a high visible light transmittance comparable to that in this embodiment was obtained for all the temperatures of 200° C., 400° C. and 500° C. Particularly, the second oxide film under the condition of 500° C. was found to have a light transmittance of 75% or more in a range of about 470 nm or more and 1000 nm or less. Therefore, it became clear that at least heat-treatment of the first oxide film 11 at a temperature of 200° C. or higher and 500° C. or lower would contribute to dramatic improvement of the visible light transmittance. These findings fundamentally apply to embodiments other than this embodiment. By producing a film of an oxide (which can contain incidental impurities) containing niobium (Nb) and copper (Cu), wherein the ratio of the number of atoms of niobium (Nb) to copper (Cu) is such that the number of atoms of niobium (Nb) is 0.5 or more and less than 3 provided that the number of atoms of copper is 1, a high visible light transmittance can be achieved. Regarding this range, the findings fundamentally apply even to the case where niobium (Nb) is replaced by tantalum (Ta). All the following analyses of the visible light transmittance were carried out using the aforementioned multi-channel spectrometer.

Thus, according to the analysis results heretofore, it is preferable to heat-treat the first oxide film 11 at a temperature of 200° C. or higher and less than 400° C. for obtaining an oxide film which has a high transmittance with high flatness maintained and shows p-type conductivity with the conductance thereof being high. In addition, it is further preferable to heat-treat the first oxide film 11 at a temperature in a range of 200° C. or higher and 300° C. or lower in particular.

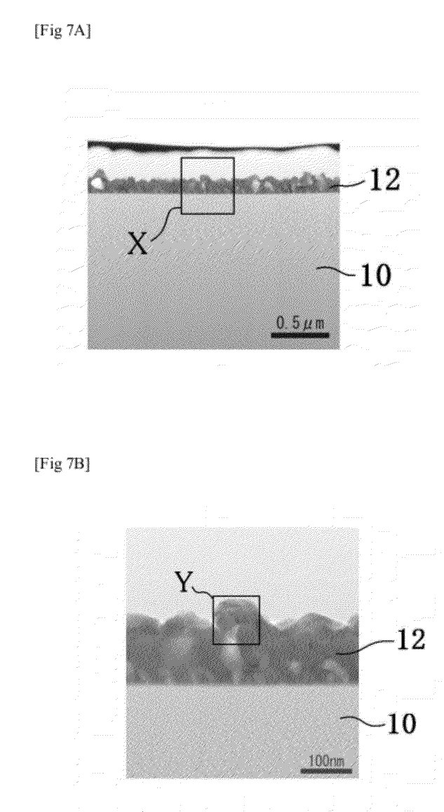

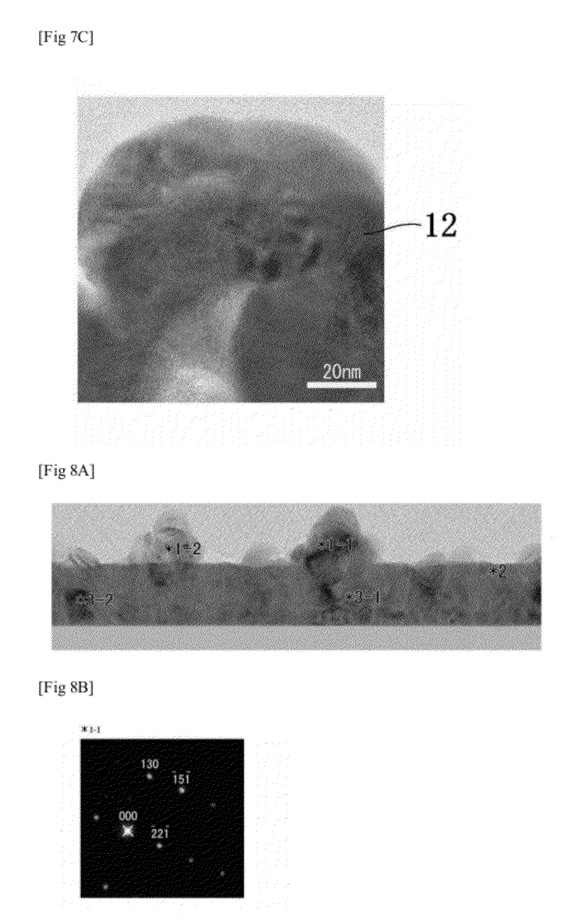

The present inventors carried out an analysis of the second oxide film 12 by an electric field emission type transmission electron microscope (TEM) (manufactured by JEOL Ltd.; Model JEM-2010F). FIG. 7A is a photograph of the observed broadest region of three analysis results for the second oxide film 12. FIG. 7B shows a photograph with a part (X part) of FIG. 7A magnified, and FIG. 7C shows a photograph with a part (Y part) of FIG. 7B magnified. As a result, the second oxide film 12 of this embodiment was observed to be constituted principally by an aggregate of granular microcrystals having a major axis of 200 nm or less as shown in FIGS. 7A to 7C. From this result, the second oxide film 12 of this embodiment is considered to be an aggregate of microcrystals or an amorphous form including microcrystals. Also, from the analysis by TEM, the thickness of the second oxide film 12 was confirmed to be about 150 nm. Further, according to an energy dispersive fluorescent X-ray (EDX) spectrometer (manufactured by NORAN Instruments, Inc.; Vantage™) carried out along with the analysis by TEM, the ratio of the number of atoms of copper (Cu) and niobium (Nb) in the second oxide film 12 was confirmed to be almost 1:1 in general although the numerical value thereof locally varied.

Conditions for the analysis by TEM are as follows. First for a sample to be analyzed, a carbon film was formed using a known high-vacuum deposition apparatus, and further a tungsten film was formed in a focused ion beam (FIB) processing apparatus for protecting the outermost surface of the sample. Subsequently, a measurement region was extracted by a micro-sampling method, and was then formed into a thin section by FIB processing. Thereafter, FIB damaged layers were removed by an ion milling apparatus (manufactured by Gatan Inc.; Model PIPS Model-691). Regarding conditions for observation by TEM, the accelerating voltage was 200 kV. The sample was observed by a CCD camera (manufactured by Gatan Inc.; ULTRASCAN™).

Conditions for the analysis by EDX are as follows. First, the quantitative determination method was a standardless method, and the calibration method was an MBTS (Metallurgical Biological Thin Section) method. The background Fit method was a Filter-Fit method. The accelerating voltage was 200 kV and the beam diameter was about 1 nm. The count time was 30 seconds per point.

Aside from this embodiment, the present inventors prepared a first oxide film and a second oxide film in the same manner as described above using an oxide sintered body having a low relative density (for example 50%), and found that the oxide films both had an increased surface roughness. Therefore it is understood that the use of an oxide sintered body having a low relative density leads to a film having a rough surface.

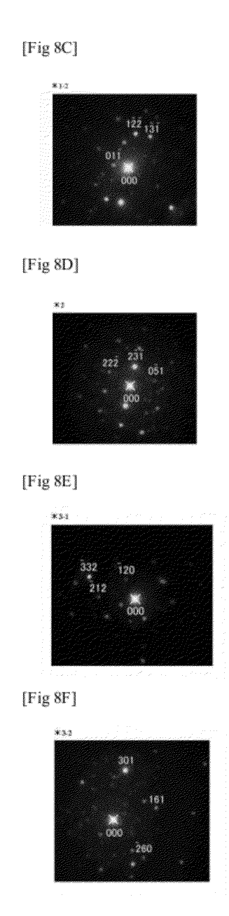

After the first oxide film 11 was formed, further additionally the analysis of the first oxide film 11 by TEM and the analysis thereof by electron diffraction analyzer (manufactured by Hitachi High-Technologies Corporation; Model HF-2000) were carried out. FIG. 8A is a TEM photograph of the first oxide film 11, and FIGS. 8B to 8F each show the result of electron diffraction analysis of a specific portion in FIG. 8A. Specifically, FIG. 8B shows the result for the portion of “1-1” in FIG. 8A, and FIG. 8C shows the result for the portion of “1-2” in FIG. 8A. FIG. 8D shows the result of the portion of “2” in FIG. 8A. FIG. 8E shows the result for the portion of “3-1” in FIG. 8A, and FIG. 8F shows the result for the portion of “3-2” in FIG. 8A. As a result of the analyses, interestingly, no peak was clearly observed except for a broad halo peak considered to result from amorphousness in the analysis of the first oxide film 11 by XRD as described above, but according to the electron diffraction, a crystal structure of Cu₃Nb₂O₈ was observed in each of the portions in FIGS. 8B and 8C. A crystal structure of NbO₂ was observed in each of the portions in FIGS. 8D and 8E. Further, a crystal structure of CuNb₂O₃ was observed in the portion in FIG. 8F. Thus, the first oxide film 11 was confirmed to be a film containing at least not only microcrystals of a complex oxide (Cu_{X}Nb_{Y}O_{Z}) of niobium (Nb) and copper (Cu) but also microcrystals of niobium oxide (Nb_{X}O_{Y}).

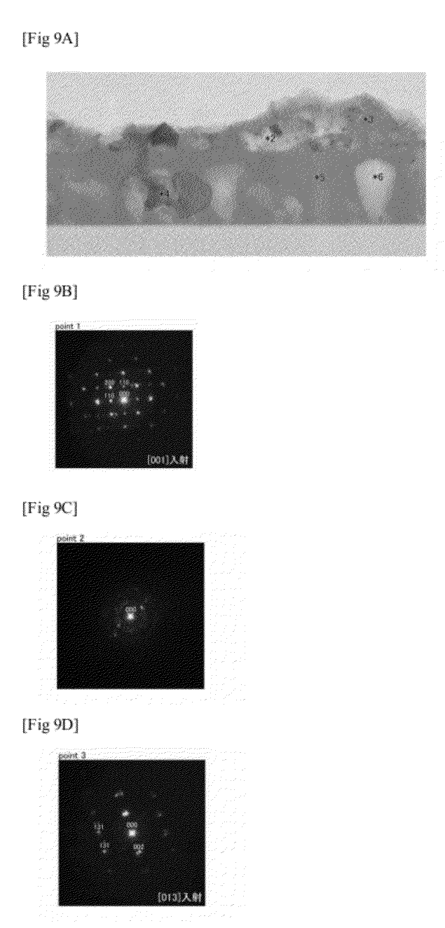

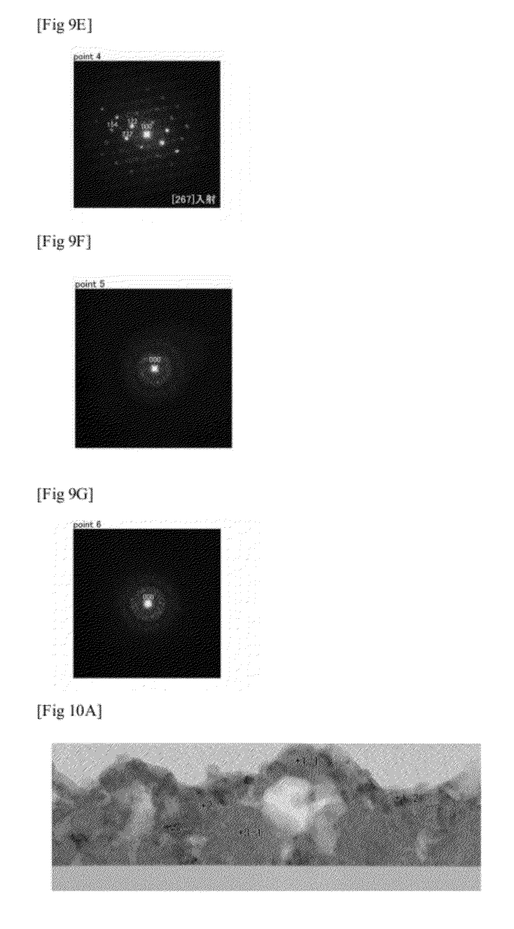

Similarly, after the second oxide film 12 was formed, the analysis of the second oxide film 12 by TEM and the analysis thereof by electron diffraction were carried out. FIG. 9A is a TEM photograph of the second oxide film 12 formed by heat-treating the first oxide film 11 at 300° C., and FIGS. 9B to 9G each show the result of electron diffraction analysis of a specific portion in FIG. 9A. Specifically, FIG. 9B shows the result for the portion of “1” in FIG. 9A, FIG. 9C shows the result for the portion of “2” in FIG. 9A, and FIG. 9D shows the result for the portion of “3” in FIG. 9A. FIG. 9E shows the result for the portion of “4” in FIG. 9A, FIG. 9F shows the result for the portion of “5” in FIG. 9A, and FIG. 9G shows the result for the portion of “6” in FIG. 9A. As a result of the analyses, interestingly, no peak was clearly observed except for a broad halo peak considered to result from amorphousness in the analysis of the second oxide film 12 by XRD as described above, but according to the electron diffraction, a crystal structure of Cu₂O was observed in each of the portions in FIGS. 9B to 9D. A crystal structure of NbO₂ was observed in each of the portions in FIGS. 9E to 9G. Thus, the second oxide film 12 was confirmed to be a film containing at least microcrystals of niobium oxide (Nb_{X}O_{y}) and microcrystals of copper oxide (Cu_{X}O_{Y}).

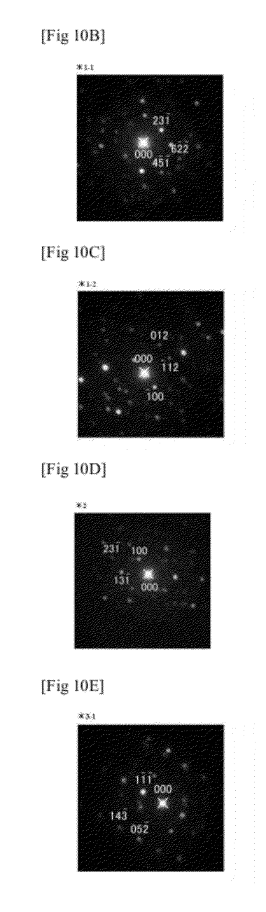

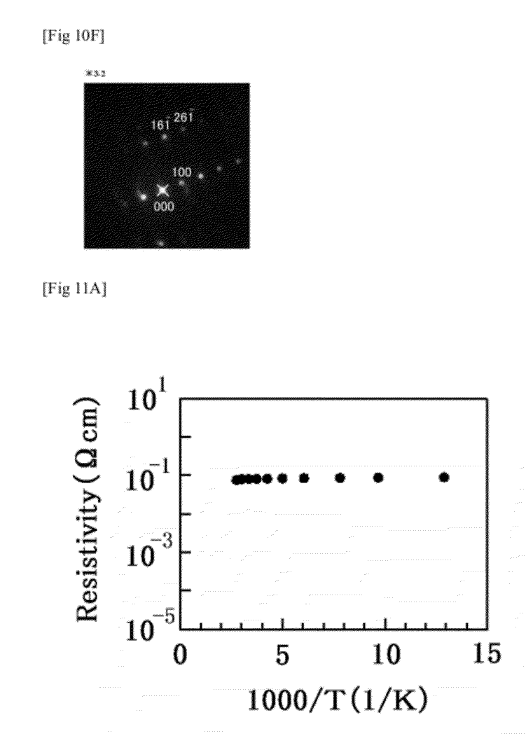

FIG. 10A is a TEM photograph of the second oxide film 12 formed by heat-treating the first oxide film 11 at 500° C., and FIGS. 10B to 10F each show the result of electron diffraction analysis of a specific portion in FIG. 10A. Specifically, FIG. 10B shows the result for the portion of “1-1” in FIG. 10A, and FIG. 10C shows the result for the portion of “1-2” in FIG. 10A. FIG. 10D shows the result of the portion of “2” in FIG. 10A. FIG. 10E shows the result for the portion of “3-1” in FIG. 10A, and FIG. 10F shows the result for the portion of “3-2” in FIG. 10A. As a result of the analyses, interestingly, no peak was clearly observed except for a broad halo peak considered to result from amorphousness in the analysis of the first oxide film 11 by XRD as described above, but according to the electron diffraction, a crystal structure of NbO₂ was observed in the portion in FIG. 10B. A crystal structure of Cu₃Nb₂O₈ was observed in the portions in FIG. 10C. A crystal structure of CuNbO₃ was observed in each of the portions in FIGS. 10D to 10F. Thus, the second oxide film 12 was confirmed to be a film containing at least not only microcrystals of a complex oxide (Cu_{X}Nb_{Y}O_{Z}) of niobium (Nb) and copper (Cu) but also microcrystals of niobium oxide (Nb_{X}O_{Y}).

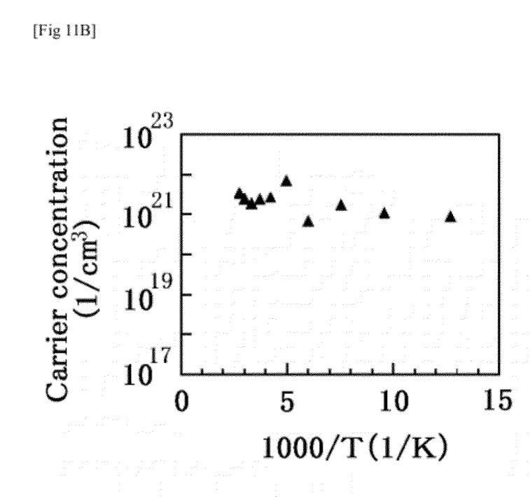

The present inventors measured a change in electrical properties to a change in temperature for the second oxide film 12 formed by heat-treating the first oxide film 11 at 300° C. The measurement of electrical properties was made using “ResiTEST 8300” manufactured by TOYO Corporation. The resistivity of a thin film was measured by the van der Pauw's method. In addition, the carrier concentration was measured by Hall measurement by the van der Pauw's method. FIG. 11A is a graph showing a change in resistivity to a change in temperature, and FIG. 11B is a graph showing a change in carrier concentration to a change in temperature.

As a result of this measurement, the resistivity and the carrier concentration hardly varied with respect to a change in temperature. Therefore, the second oxide film 12 was found to show a behavior similar to that of a degenerate semiconductor in electrical properties.

### Variation (1) of First Embodiment

A first oxide film 11 and a second oxide film 12 were formed under the same conditions as in the first embodiment except that the temperature of the stage 27 was 20° C. to 25° C. (so called room temperature) among conditions for the pulse laser deposition apparatus 20 in the first embodiment. Therefore, descriptions that overlap with those of the first embodiment can be omitted.

As a result of an analysis by AFM, it became clear that the first oxide film 11 in this embodiment had a surface roughness of about 1 nm and the second oxide film 12 had a surface roughness of 1.7 nm or more and 2.3 nm or less. According to an XRD analysis, the second oxide film 12 of this embodiment is also considered to be an aggregate of microcrystals, an amorphous form including microcrystals or an amorphous form. When considering in combination with the results of examination and analysis carried out aside from this embodiment, the temperature (set temperature) of the stage 27 in production of the first oxide film 11 is preferably, in particular, 0° C. or higher and 100° C. or lower for obtaining extremely high flatness as described previously.

The first oxide film 11 in this embodiment had n-type conductivity and had a conductance of about 0.061 S/cm. However, the second oxide film 12 had p-type conductivity and had a conductance of about 4.22 S/cm. Further, the transmittance of the first oxide film 11 in this embodiment to visible light having a wavelength of 500 nm or more and 800 nm or less was about 40% or less. On the other hand, the transmittance of the second oxide film 12 in this embodiment to visible light having a wavelength of about 580 nm or more and 1000 nm or less was 60% or more.

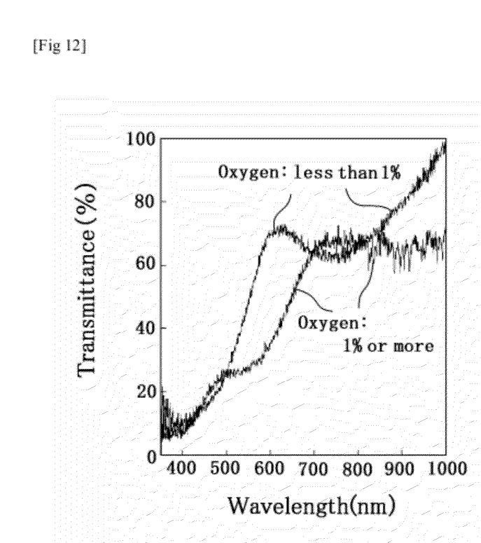

As described above, it became clear that heating of the first oxide film 11 would significantly contribute for improvement of conductivity as a p-type and visible light transmittance. The results of carrying out heat treatment under the same conditions as in the first embodiment except that the first oxide film 11 formed in the first embodiment was heated in an atmosphere where oxygen existed in an amount of 1% or more were also examined. As a result, it was found that as shown in FIG. 12, the visible light transmittance of the oxide film after heat treatment under conditions of variation (1) of the first embodiment was much lower than the transmittance of the second oxide film 12 in the first embodiment to a light ray having a wavelength of 500 nm or more and 1000 nm or less except for some regions. This tendency is confirmed in the first embodiment and a second embodiment described later. Therefore, it can be said that it is not preferable from the viewpoint of visible light transmittance to heat-treat the first oxide film 11 under an atmosphere where oxygen (O₂) exists in a predetermined amount or more. The present inventors presumes that this is attributed to coloring of the film due to a change of the valence number of copper in the first oxide film 11 from 1 to 2 by oxygen in the atmosphere in the heat treatment.

### Comparative Example of First Embodiment

As a comparative example, the first oxide film 11 formed in the first embodiment was heat-treated in an atmosphere at 500° C. For the sake of convenience, this oxide film after heat treatment is referred to as a third oxide film. Conditions other than the aforementioned condition are the same as those for the processes in the first embodiment. Therefore, descriptions that overlap with those of the first embodiment can be omitted.

According to an analysis of a visible light transmittance by the present inventors, it was found that the third oxide film of this embodiment was considered to be a thin film containing bivalent copper (Cu). Therefore, it is considered that by heating in an atmosphere, monovalent copper (Cu) was oxidized by oxygen in air and consequently formed into bivalent copper (Cu). As a result of an XRD analysis, the third oxide film is considered to be an aggregate of microcrystals, an amorphous form including microcrystals or an amorphous form, which shows no clear diffraction peak in the XRD analysis.

### Second Embodiment

In this embodiment, copper oxide, i.e. an oxide of monovalent copper and an oxide of pentavalent niobium, which were starting materials of an oxide sintered body for forming the first oxide film 11 of the first embodiment, were mixed so that the stoichiometric ratio of Nb and Cu was almost 3:1. Besides this, conditions are the same as those for the processes in the first embodiment. Therefore, descriptions that overlap with those of the first embodiment can be omitted.

Thereafter, in the same manner as in the first embodiment, an oxide sintered body is produced through a compression-molding step by a tablet molding machine and a baking step. The oxide sintered body of this embodiment has a relative density of about 86%. As a result of an XRD analysis of the oxide sintered body, it was found to have a crystal structure of CuNb₃O₈.

Thereafter, in the same manner as in the first embodiment, a first oxide film was produced on a substrate 10 using a pulse laser deposition apparatus 20 shown in FIG. 1. The oxide sintered body having a crystal structure of CuNb₃O₈ was employed as a target 30.

In this embodiment, the temperature of a heater (not shown) within a stage 27 was set to 20° C. to 25° C. (so called room temperature). In addition, oxygen (O₂) was fed into a chamber 21, evacuation by a vacuum pump 29 was then adjusted so that the equilibrium pressure of oxygen within the chamber 21 was 0.027 Pa. Thereafter, in the same manner as in the first embodiment, the first oxide film 11 is formed on the substrate 10 as shown in FIG. 2A by a pulse krypton fluoride (KrF) excimer laser (wavelength 248 nm) 22.

Further, after formation of the first oxide film 11, the first oxide film 11 on the substrate 10 was heat-treated (annealed) under a condition of 300° C. for 2 hours within a chamber having an atmosphere that had an oxygen concentration of less than 1% by feeding nitrogen (N₂) gas in the same manner as in the first embodiment. As a result, a second oxide film 12 was formed on the substrate 10 as shown in FIG. 2B.

The present inventors observed the surfaces of the first oxide film 11 and the second oxide film 12 obtained in this embodiment by an atomic force microscope. As a result, the first oxide film 11 was found to be a very flat film. On the other hand, several patterns considered as granular matters were visually recognized for the second oxide film 12. The thickness of the second oxide film 12 was measured using the laser microscope, and resultantly found to be about 350 nm.

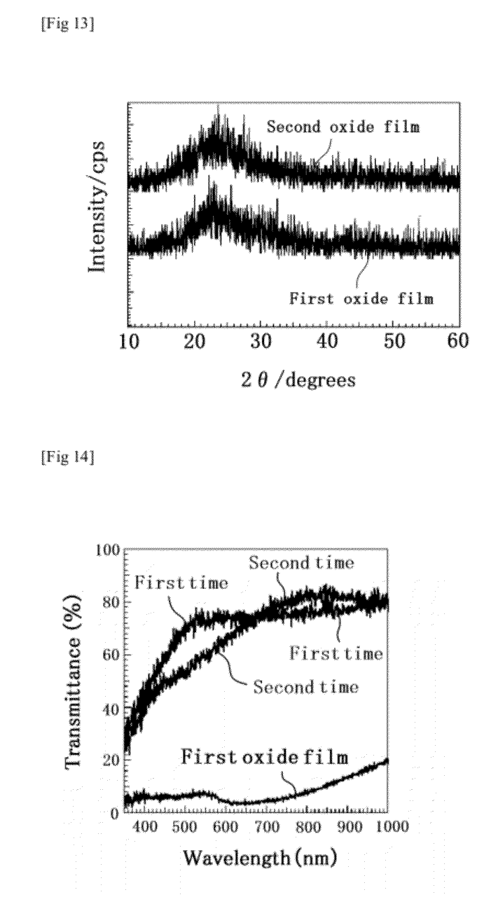

The present inventors analyzed the crystal conditions of the first oxide film 11 and the second oxide film 12 by XRD (X-ray diffraction). As a result, for both the first oxide film 11 and the second oxide film 12, no peak was observed at 2θ of 20° to 30° except for a halo peak considered to result from amorphousness as shown in FIG. 13. Therefore, when considering the results of the XRD analysis, both the first oxide film 11 and the second oxide film 12 are considered to be aggregates of microcrystals, amorphous forms including microcrystals or amorphous forms, which show no clear diffraction peak in the XRD analysis.

The present inventors analyzed the electrical properties and conductivity of the first oxide film 11 and the second oxide film 12 and resultantly, the first oxide film 11 of this embodiment had p-type conductivity, and had a conductance of about 0.286 S/cm. However, the second oxide film 12 of this embodiment had p-type conductivity, but had a conductance of about 0.0006 S/cm. Therefore, in the case of this embodiment, a phenomenon was observed in which the conductance was reduced by the heat treatment.

The present inventors analyzed the visible light transmittances of the first oxide film 11 and the second oxide film 12. As a result, the transmittance was confirmed to be improved by the heat treatment also in the case of this embodiment.

### Variation (1) of Second Embodiment

A first oxide film 11 and a second oxide film 12 were formed under the same conditions as in the first embodiment, aside from some results (1.11 in Table 1 (third time)) described later, except that the equilibrium pressure of oxygen within the chamber 21 was 0.0027 Pa among conditions for the pulse laser deposition apparatus 20 in the first or second embodiment, and the oxide sintered body in the second embodiment had a stoichiometric ratio of copper (Cu) and niobium (Nb) in the target 30. Therefore, descriptions that overlap with those of the first embodiment can be omitted.

The present inventors measured electrical and optical properties for second oxide films 12 formed by heat-treating, under several temperature conditions, the first oxide film 11 formed using targets 30 with varied ratios of niobium (Nb) to copper (Cu). Table 1 shows the results of the measurements. FIG. 14 is a chart showing the result of analyzing the transmittance of a part of the second oxide film 12 formed by heat-treating the first oxide film 11 at 300° C. to a light ray having a wavelength principally in a visible light region, where the target 30 with the number of atoms of niobium (Nb) being 1.11 provided that the number of atoms of copper (Cu) is 1 is used, among the results shown in Table 1. Charts with the ratios of niobium (Nb) to copper (Cu) in Table 1 being 1.11 (first time) and 1.11 (second time) are marked with “first time” and “second time”, respectively, in the chart of FIG. 14. For reference, a chart of the transmittance of the first oxide film 11 before being heat-treated is also drawn in FIG. 14. Only for the ratio of 1.11 (third time), the number of irradiations with the excimer laser in the first embodiment was set to 50,000 in addition to the points of difference described above.

TABLE 1

| | Temperature | | | | | | |
|---|---|---|---|---|---|---|---|
| | (° C.) for | | | | | | |
| | heat-treating | | Hall | Carrier | | | |
| Ratio of Nb to | first oxide | Conductance | coefficient | concentration | Mobility | | |
| Cu (Cu = 1) | film | (S/cm) | (cm³/C) | (1/cm³) | (cm²/Vs) | Type | Transmittance |
| 1.5 | 300 | 269 | 1.07 × 10⁻⁴ | 5.84 × 10²² | 2.87 × 10⁻² | P | 20% |
| 1.11 | 300 | 41.1 | 2.17 × 10⁻² | 2.86 × 10²⁰ | 8.93 × 10⁻¹ | P | 70% or more |
| (First time) | | | | | | | |
| 1.11 | 300 | 63.0 | 1.13 × 10⁻² | 5.53 × 10²⁰ | 7.11 × 10⁻¹ | P | 60% |
| (Second time) | | | | | | | |
| 1.11 | 300 | 116 | 3.10 × 10⁻³ | 2.10 × 10²¹ | 3.59 × 10⁻¹ | P | 60% or more |
| (Third time) | | | | | | | |
| 1 | 300 | 21.2 | 1.74 × 10⁻² | 3.59 × 10²⁰ | 3.69 × 10⁻¹ | P | 80% or more |
| 0.66 | 300 | 5.11 | 5.97 × 10⁻² | 1.05 × 10¹⁹ | 1.05 × 10⁻¹ | P | 40% or more |
| 0.25 | 300 | 7.92 | 2.76 × 10⁻¹ | 2.26 × 10¹⁹ | 2.19 | P | 15% |
| 0.25 | 500 | 43.8 | 2.41 × 10¹ | 2.59 × 10¹⁷ | 1.06 × 10³ | P | 20% |

In each of the first and second embodiments, raw materials (for example Cu₂O and Nb₂O₅) are mixed at a specific ratio in production of an oxide sintered body as a raw material for forming an oxide film as a final object, but it can be understood that the ratio thereof is not limited to those in the embodiments as shown in Table 1 and FIG. 14. That is, it can be understood that for the second oxide film formed by heat-treating the first oxide film 11 at 300° C., the transmittance and the conductance of a p-type are both remarkably increased when the number of atoms of niobium (Nb) is 1 or 1.1 provided that the number of atoms of copper (Cu) is 1. Particularly, the result with the number of atoms of niobium (Nb) being 1.5 provided that the number of atoms of copper (Cu) is 1, and the second and third results with the number of atoms of niobium (Nb) being 1.5 provided that the number of atoms of copper (Cu) is 1.1 show levels of outstandingly excellent conductances. It has become clear that even in the case of ratios other than those stated above, a high conductivity of a p-type (at least 1 S/cm, or 5 S/cm or more if the range is further narrowed) is obtained when the number of atoms of niobium (Nb) is 0.66 or 0.25 provided that the number of atoms of copper (Cu) is 1. “Transmittance” in Table 1 is described as a value obtained as an average transmittance in a range of wavelengths of 400 nm or more and 800 nm or less.

According to additional examinations by the present inventors, an oxide film having properties comparable to properties shown in at least a part of Table 1 above can be produced as long as the number of atoms of niobium (Nb) is 0.25 or more and 4 or less provided that the number of atoms of copper (Cu) is 1 for the ratio of raw materials in the oxide sintered body. This finding also applies to the ratio of the number of atoms of tantalum (Ta) to copper (Cu). Similarly, according to additional examinations by the present inventors, a preferable range of the stoichiometric ratio of copper (Cu) and niobium (Nb) in the target 30 is such that the number of atoms of niobium (Nb) is 0.66 or more and 1.5 or less provided that the number of atoms of copper (Cu) is 1 from the viewpoint of improvement of electrical properties. The range is more preferably such that the number of atoms of niobium (Nb) is 0.66 or more and 1.25 or less provided that the number of atoms of copper (Cu) is 1 from the viewpoint of improvement of the transmittance and the electrical properties. The range is further preferably such that the number of atoms of niobium (Nb) is 0.66 or more and 1.11 or less provided that the number of atoms of copper (Cu) is 1 from the above two viewpoints. In addition, the range is most preferably such that the number of atoms of niobium (Nb) is 1 or more and 1.11 or less provided that the number of atoms of copper (Cu) is 1.

### Third Embodiment

In this embodiment, prior to production of an oxide film as a final object, an oxide sintered body as a raw material for forming the oxide film was produced. First, copper oxide (Cu₂O), i.e. an oxide of monovalent copper (Cu) and (Ta₂O₅), i.e. an oxide of pentavalent tantalum (Ta) were physically mixed. In this embodiment, the oxides were mixed using the grinding mixer described above. The two oxides were mixed so that the stoichiometric ratio of Ta and Cu was almost 1:1. Besides this, conditions are the same as those for the processes in the first embodiment. Therefore, descriptions that overlap with those of the first embodiment can be omitted. For copper oxide (Cu₂O) of this embodiment, copper oxide manufactured by Kojundo Chemical Lab. Co., Ltd. and having a nominal purity of 99.9% was employed. For Ta₂O₅ of this embodiment, Ta₂O₅ manufactured by Kojundo Chemical Lab. Co., Ltd. and having a nominal purity of 99.9% was employed.

Thereafter, in the same manner as in the first embodiment, an oxide sintered body is produced through a compression-molding step by a tablet molding machine and a baking step. The oxide sintered body of this embodiment has a relative density of about 88%. As a result of an XRD analysis of the oxide sintered body, it was found to have a crystal structure of CuTaO₃.

Thereafter, in the same manner as in the first embodiment, a first oxide film is produced on a substrate 10 using a pulse laser deposition apparatus 20 shown in FIG. 1. The oxide sintered body having a crystal structure of CuTaO₃ was employed as a target 30.

In this embodiment, the temperature of a heater (not shown) within a stage 27 was set to 20° C. to 25° C. (so called room temperature). In addition, oxygen (O₂) was fed into a chamber 21, evacuation by a vacuum pump 29 was then adjusted so that the equilibrium pressure of oxygen within the chamber 21 was 0.13 Pa. Thereafter, in the same manner as in the first embodiment, the first oxide film 11 is formed on the substrate 10 as shown in FIG. 2A by a pulse krypton fluoride (KrF) excimer laser (wavelength 248 nm) 22.

Further, after formation of the oxide film 11, the first oxide film 11 on the substrate 10 was heat-treated (annealed) under a condition of 300° C. for 2 hours within a chamber having an atmosphere that had an oxygen concentration of less than 1% by feeding nitrogen (N₂) gas in the same manner as in the first embodiment. As a result, a second oxide film 12 was formed on the substrate 10 as shown in FIG. 2B.

The present inventors observed the surfaces of the first oxide film 11 and the second oxide film 12 obtained in this embodiment by an atomic force microscope. As a result, the first oxide film 11 was found to be a very flat film. On the other hand, several patterns considered as granular matters were visually recognized for the second oxide film 12. The thickness of the second oxide film 12 was measured using a laser microscope, and resultantly found to be about 280 nm.

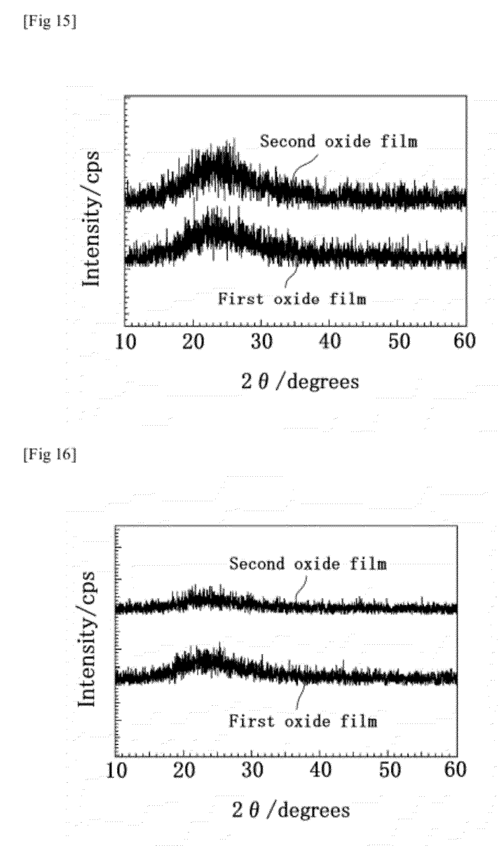

The present inventors analyzed the crystal conditions of the first oxide film 11 and the second oxide film 12 by XRD (X-ray diffraction). As a result, for both the first oxide film 11 and the second oxide film 12, no peak was observed at 2θ of 20° to 30° except for a halo peak considered to result from amorphousness as shown in FIG. 15. Further, when the first oxide film 11 was heat-treated under a condition of 500° C. for 2 hours, aside from this embodiment, no peak was observed except for a halo peak considered to result from amorphousness. Therefore, when considering the results of the XRD analysis, both the first oxide film 11 and the second oxide film 12 are considered to be aggregates of microcrystals, amorphous forms including microcrystals or amorphous forms, which show no clear diffraction peak in the XRD analysis.

The present inventors analyzed the electrical properties and conductivity of the first oxide film 11 and the second oxide film 12 and resultantly, the first oxide film 11 of this embodiment had p-type conductivity, and had a conductance of about 2.40 S/cm. However, the second oxide film 12 of this embodiment had p-type conductivity, but had a conductance of about 0.0086 S/cm. Therefore, in the case of this embodiment, a phenomenon was observed in which the conductance was reduced by the heat treatment.

The present inventors analyzed the visible light transmittances of the first oxide film 11 and the second oxide film 12. As a result, the transmittance of the first oxide film 11 to a light ray having a wavelength of 400 nm or more and 800 nm or less was 30% or less, but the transmittance of the second oxide film 12 in the same range was improved. On the other hand, as a result of heat-treating the first oxide film 11 under a condition of 500° C. for 2 hours aside from this embodiment, the transmittance to a light ray having a wavelength of at least 500 nm or more and 800 nm or less was increased to 60% or more. Particularly, the transmittance to a light ray having a wavelength of about 550 nm or more and 800 nm or less was 70% or more. Therefore, the transmittance was confirmed to be improved by the heat treatment also in the case of this embodiment.

### Forth Embodiment

In this embodiment, copper oxide, i.e. an oxide of monovalent oxide and an oxide of pentavalent tantalum, which were starting materials of an oxide sintered body for forming the first oxide film 11 of the third embodiment, were mixed so that the stoichiometric ratio of Ta and Cu was almost 3:1. Besides this, conditions are same as those for the processes in the first embodiment. Therefore, descriptions that overlap with those of the first embodiment can be omitted.

Thereafter, in the same manner as in the first embodiment, an oxide sintered body is produced through a compression-molding step by a tablet molding machine and a baking step. The oxide sintered body of this embodiment has a relative density of about 55%. The oxide sintered body is considered to be a mixed crystal of a complex oxide unknown at present and Ta₂O₅.

Thereafter, in the same manner as in the first embodiment, a first oxide film is produced on a substrate 10 using a pulse laser deposition apparatus 20 shown in FIG. 1. An oxide sintered body of CuTa₃O₈ having the above-mentioned crystal structure was employed as a target 30.

In this embodiment, the temperature of a heater (not shown) within a stage 27 was set to 20° C. to 25° C. (so called room temperature). In addition, oxygen (O₂) was fed into a chamber 21, evacuation by a vacuum pump 29 was then adjusted so that the equilibrium pressure of oxygen within the chamber 21 was 0.13 Pa. Thereafter, in the same manner as in the first embodiment, the first oxide film 11 is formed on the substrate 10 as shown in FIG. 2A by a pulse krypton fluoride (KrF) excimer laser (wavelength 248 nm) 22. Here, as a result of making an observation using a laser microscope, the first oxide 11 was found to be a flat film.

Further, after formation of the oxide film 11, the first oxide film 11 on the substrate 10 was heat-treated (annealed) under a condition of 300° C. for 2 hours within a chamber having an atmosphere that had an oxygen concentration of less than 1% by feeding nitrogen (N₂) gas in the same manner as in the first embodiment. As a result, a second oxide film 12 was formed on the substrate 10 as shown in FIG. 2B.

The thickness of the second oxide film 12 was measured using a laser microscope, and resultantly found to be about 190 nm.

The present inventors analyzed the crystal conditions of the first oxide film 11 and the second oxide film 12 by XRD (X-ray diffraction). As a result, for both the first oxide film 11 and the second oxide film 12, no peak was observed at 2θ of 20° to 30° except for a halo peak considered to result from amorphousness as shown in FIG. 16. Further, when the first oxide film 11 was heat-treated under a condition of 500° C. for 2 hours, aside from this embodiment, no peak was observed except for a halo peak considered to result from amorphousness. Therefore, when considering the results of the XRD analysis, both the first oxide film 11 and the second oxide film 12 are considered to be aggregates of microcrystals, amorphous forms including microcrystals or amorphous forms, which show no clear diffraction peak in the XRD analysis.

The present inventors analyzed the visible light transmittances of the first oxide film 11 and the second oxide film 12. As a result, the transmittance was confirmed to be improved by the heat treatment also in the case of this embodiment.

In the embodiments described above, the first oxide film 11 is produced using the pulse laser deposition apparatus 20, but the method for producing the first oxide film 11 is not limited thereto. For example, a physical vapor deposition method (PVD method) represented by an RF sputtering method or a magnetron sputtering method can be applied.

For example, the following results have been obtained when using the RF sputtering method.

### Other Embodiments

A first oxide film 11 was formed using a high-frequency sputtering apparatus (RF sputtering apparatus) (manufactured by Eiko Co., Ltd.) having a known structure. At this time, high-frequency power was set to 90 W. A sputtering gas to a target 30 was a mixed gas with argon (Ar) and oxygen (O₂) mixed in a ratio of 95:5, and the pressure during film formation was 5.0 Pa. A substrate, on which the first oxide film 11 was formed, was a borosilicate glass substrate, and the temperature of a stage, on which the substrate was placed, was room temperature (20° C. to 25° C.). However, elevation of the temperature particularly of the surface of the substrate (probably 100° C. or lower) during a step of forming a film by the sputtering method cannot be avoided. The distance between the target and the substrate was 150 mm. The target used in this embodiment was the target 30, which was the same as that of the first embodiment except that the number of atoms of niobium (Nb) is 1 provided that the number of atoms of copper (Cu) is 3. A film formation process was carried out for 60 minutes under these conditions.

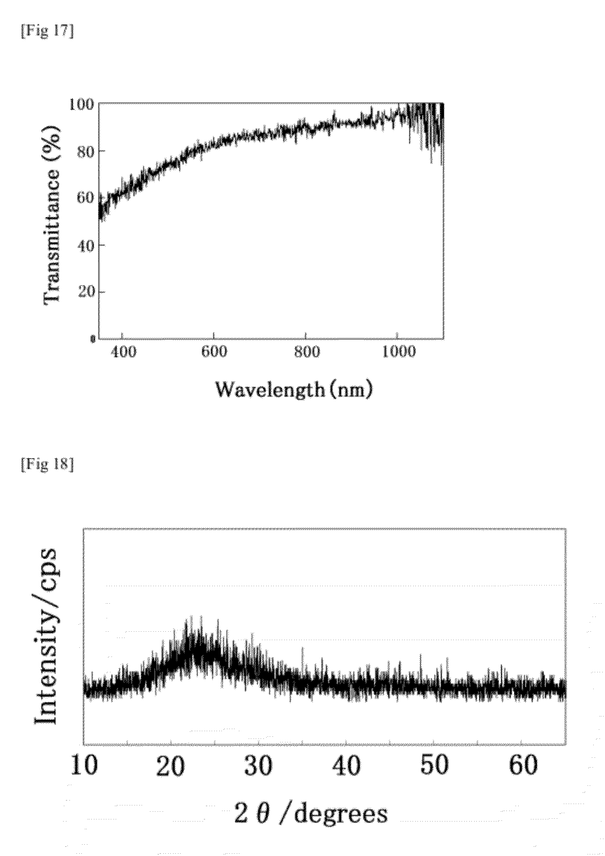

FIG. 17 is a chart showing the result of analysis of the transmittance of the first oxide film 11 obtained by the RF sputtering method to a light ray having a wavelength principally in a visible light region. It became clear that the first oxide film 11 had a transmittance of 80% or more in a visible light region having a wavelength of about 600 nm or more as shown in FIG. 17. A high value of transmittance of 60% or more was obtained even in a region having a wavelength of about 400 nm or more and 600 nm or less. Further, it was found that the first oxide film 11 was of a p-type and had a conductance of 0.106 S/cm as a result of measuring the electrical properties thereof. It also became clear that the first oxide film was a film having relatively low resistance because the resistivity was 94.3 Ωcm. The first oxide film 11 had a carrier concentration of 1.91×10¹⁷ (1/cm³) and the mobility thereof was 0.348 (cm³/Vs).

Further, the present inventors analyzed the crystal condition of the first oxide film 11 by XRD (X-ray diffraction). As a result, for the first oxide film 11, no peak was clearly observed at 2θ of 20° to 30° except for a broad halo peak considered to result from amorphousness as shown in FIG. 18.

Incidentally, in the first embodiment, the ratio of the number of atoms of niobium (Nb) to copper (Cu) contained in the second oxide film 12 was such that the number of atoms of the niobium (Nb) is 1 provided that the number of atoms of the copper (Cu) is 1, but the ratio of the number of atoms is not limited to the value. For example, an effect comparable to that of the first embodiment can be exhibited as long as the ratio of the number of atoms of niobium (Nb) to copper (Cu) contained in the second oxide film 12 is such that the number of atoms of the niobium (Nb) is 0.5 or more and 4 or less provided that the number of atoms of the copper (Cu) is 1. Particularly, the second oxide film in this range of the ratio of the number of atoms has an increased transmittance (for example 60% or more) to visible light having a wavelength of 500 nm or more and 800 nm or less. The second oxide film in the aforementioned range of the ratio of the number of atoms is considered to be an aggregate of microcrystals, an amorphous form including microcrystals or an amorphous form, which shows no clear diffraction peak in the XRD analysis, but according to electron diffraction analysis, existence of microcrystals has been confirmed. Therefore, it is interesting that the result of measuring the state of the second oxide film varies at least apparently depending on the measurement method.

In the embodiments described above, an oxide sintered body is produced from an oxide as the target 30 for producing the first oxide film 11 or the second oxide film 12, but an oxide sintered body may be produced from a hydroxide (e.g., copper hydroxide), a nitrate (e.g., copper nitrate), a carbonate or an oxalate.

As described above, variations within the scope of the present invention including other combinations of the embodiments are also included in claims.

### INDUSTRIAL APPLICABILITY

The present invention can be widely used as an oxide film having p-type conductivity or a transparent conductive film having p-type conductivity.

1-17. (canceled)

18. An oxide film (which can contain incidental impurities) comprising niobium (Nb) and copper (Cu), wherein the oxide film is an aggregate of microcrystals, an amorphous form containing microcrystals or an amorphous form, and has p-type conductivity.

19. The oxide film according to claim 18, wherein the ratio of the number of atoms of the niobium (Nb) to the copper (Cu) is such that the number of atoms of the niobium (Nb) is 0.5 or more and less than 3 provided that the number of atoms of the copper (Cu) is 1.

20. The oxide film according to claim 18, wherein the oxide film is an aggregate of microcrystals or an amorphous form comprising microcrystals, and has a conductance of 1 S/cm or more.

21. The oxide film according to claim 18, wherein the transmittance to a light ray having a wavelength of 400 nm or more and 800 nm or less is 40% or more.

22. The oxide film according to claim 18, wherein the root mean square roughness (RMS) of a surface is 1 nm or more and 50 nm or less.

23. The oxide film according to claim 18, wherein the valence number of the copper (Cu) is 1.

24. A method for producing an oxide film, comprising a step of scattering constituent atoms of a target of an oxide (which can contain incidental impurities) including niobium (Nb) and copper (Cu) to form on a substrate a first oxide film (which can contain incidental impurities) which is an aggregate of microcrystals, an amorphous form containing microcrystals or an amorphous form and has p-type conductivity.

25. The method for producing an oxide film according to claim 24, wherein the ratio of the number of atoms of the niobium (Nb) to the copper (Cu) is such that the number of atoms of the niobium (Nb) is 0.5 or more and less than 3 provided that the number of atoms of the copper (Cu) is 1.

26. The method for producing an oxide film according to claim 24, further comprising a step of forming a second oxide film by heating the first oxide film at 200° C. or higher and 500° C. or lower under an environment having an oxygen concentration of less than 1%.

27. The method for producing an oxide film according to claim 24, further comprising a step of forming a second oxide film by heating the first oxide film at 200° C. or higher and less than 400° C. under an environment having an oxygen concentration of less than 1%.

28. The method for producing an oxide film according to claim 24, wherein the temperature of the substrate at the time of forming the first oxide film is 0° C. or higher and 500° C. or lower.

29. The method for producing an oxide film according to claim 24, wherein the first oxide film is formed by scattering the constituent atoms of a target by sputtering or irradiation of a pulse laser.

30. A target which is an oxide (which can contain incidental impurities) comprising niobium (Nb) and copper (Cu), wherein
the ratio of the number of atoms of the niobium (Nb) to the copper (Cu) is 0.25 or more and 4 or less provided that the number of atoms of the copper (Cu) is 1.

31. The target according to claim 30, wherein the ratio of the number of atoms of the niobium (Nb) to the copper (Cu) is such that the number of atoms of the niobium (Nb) is 0.66 or more and 1.5 or less provided that the number of atoms of the copper (Cu) is 1.

32. The target according to claim 30, which is obtained by sintering the target and has a relative density of 55% or more.

33. A method for producing an oxide sintered body, comprising:
a mixing step of obtaining a mixture by mixing an oxide (which can contain incidental impurities) of niobium (Nb) and an oxide (which can contain incidental impurities) of copper (Cu) in a ratio such that the ratio of the number of atoms of the niobium (Nb) to the copper (Cu) is 0.25 or more and 4 or less provided that the number of atoms of the copper (Cu) is 1;
a molding step of obtaining a molded product by compression-molding the mixture, and;
a sintering step of sintering the molded product by heating the molded product.

34. The method for producing an oxide sintered body according to claim 33, wherein the ratio of the number of atoms of the niobium (Nb) to the copper (Cu) is such that the number of atoms of the niobium (Nb) is 0.66 or more and 1.5 or less provided that the number of atoms of the copper (Cu) is 1.

35. The oxide film according to claim 19, wherein the oxide film is an aggregate of microcrystals or an amorphous form comprising microcrystals, and has a conductance of 1 S/cm or more.

36. The oxide film according to claim 19, wherein the transmittance to a light ray having a wavelength of 400 nm or more and 800 nm or less is 40% or more.

37. The oxide film according to claim 19, wherein the root mean square roughness (RMS) of a surface is 1 nm or more and 50 nm or less.

38. The oxide film according to claim 19, wherein the valence number of the copper (Cu) is 1.

39. The method for producing an oxide film according to claim 25, further comprising a step of forming a second oxide film by heating the first oxide film at 200° C. or higher and 500° C. or lower under an environment having an oxygen concentration of less than 1%.

40. The method for producing an oxide film according to claim 25, further comprising a step of forming a second oxide film by heating the first oxide film at 200° C. or higher and less than 400° C. under an environment having an oxygen concentration of less than 1%.

41. The method for producing an oxide film according to claim 25, wherein the temperature of the substrate at the time of forming the first oxide film is 0° C. or higher and 500° C. or lower.

42. The method for producing an oxide film according to claim 25, wherein the first oxide film is formed by scattering the constituent atoms of a target by sputtering or irradiation of a pulse laser.

43. The target according to claims 31, which is obtained by sintering the target and has a relative density of 55% or more.
